(19) United States
(12) Patent Application Publication
(10) Pub. No.: US 2023/0343802 A1
(43) Pub. Date: Oct. 26, 2023

(54) SOLID-STATE IMAGING DEVICE AND ELECTRONIC DEVICE

(71) Applicant: SONY SEMICONDUCTOR SOLUTIONS CORPORATION, Kanagawa (JP)

(72) Inventor: Takayuki OGASAHARA, Kanagawa (JP)

(73) Assignee: SONY SEMICONDUCTOR SOLUTIONS CORPORATION, Kanagawa (JP)

(21) Appl. No.: 17/800,618

(22) PCT Filed: Jan. 7, 2021
(86) PCT No.: PCT/JP2021/000379

§ 371 Date: Aug. 18, 2022

(30) Foreign Application Priority Data
Feb. 26, 2020 (JP) 2020-030457

(51) Int. Cl. H01L 27/146

(52) U.S. Cl. CPC H01L 27/14621; H01L 27/14605; H01L 27/14627

(57) ABSTRACT

A solid-state imaging device that can obtain an image with high color reproducibility. The solid-state imaging device includes a pixel array unit having a plurality of pixel unit groups, the pixel unit groups including pixel units arranged in a 2×2 matrix, the pixel units including pixels arranged in a m×n matrix, the pixels having a photoelectric conversion unit and a color filter. Each of the pixel unit groups includes an R-filter as the color filter in one of the four pixel units, includes a G-filter as the color filter in two of the four pixel units, and includes a B-filter as the color filter in one of the four pixel units. At least one of the pixel unit groups includes a predetermined color filter having a transmittance peak wavelength different from any one of the R-filter, the G-filter, and the B-filter as the color filter.

### TECHNICAL FIELD

The present technology relates to a solid-state imaging device and an electronic device.

### BACKGROUND ART

Conventionally, a solid-state imaging device having a configuration in which one pixel of a Bayer array is divided into a plurality of pixels has been proposed (see, for example, Patent Literature 1). In the solid-state image sensor described in Patent Document 1, a high-resolution captured image can be obtained by performing full-resolution demosaic processing (a series of processes in which demosaic processing is performed after remosaic processing). In addition, a captured image with an excellent SN ratio can be obtained by performing binning processing. Furthermore, a captured image with a high dynamic range (HDR) can be obtained by changing the exposure conditions for each of a plurality of pixels.

### CITATION LIST

### Patent Literature

[PTL 1] JP 2019-175912A

### SUMMARY

### Technical Problem

In such a solid-state imaging device, further improvement in color reproducibility of the captured image is required.

An object of the present disclosure is to provide a solid-state imaging device and an electronic device capable of improving the color reproducibility of a captured image.

### Solution to Problem

A solid-state imaging device of the present disclosure includes: (a) a pixel array unit in which a plurality of pixel unit groups is arranged, the pixel unit group being composed of pixel units arranged in a 2×2 matrix, the pixel unit being composed of pixels arranged in a m_{X}n matrix (m and n are natural numbers of 2 or more), the pixel having a photoelectric conversion unit and a color filter formed corresponding to the photoelectric conversion unit, wherein (b) each of the pixel unit groups includes an R-filter as the color filter in one of the four pixel units constituting the pixel unit group, includes a G-filter as the color filter in two of the four pixel units, and includes a B-filter as the color filter in one of the four pixel units, and (c) at least one of the pixel unit group includes a predetermined color filter having a transmittance peak wavelength different from any one of the R-filter, the G-filter, and the B-filter as the color filter.

An electronic device of the present disclosure includes: (a) a solid-state imaging device including a pixel array unit in which a plurality of pixel unit groups is arranged, the pixel unit group being composed of pixel units arranged in a 2×2 matrix, the pixel unit being composed of pixels arranged in a ₘ×ₙ matrix (m and n are natural numbers of 2 or more), the pixel having a photoelectric conversion unit and a color filter formed corresponding to the photoelectric conversion unit, each of the pixel unit groups including an R-filter as the color filter in one of the four pixel units constituting the pixel unit group, a G-filter as the color filter in two of the four pixel units, and a B-filter as the color filter in one of the four pixel units, and at least one of the pixel unit group including a predetermined color filter having a transmittance peak wavelength different from any one of the R-filter, the G-filter, and the B-filter as the color filter; (b) an optical lens that forms an image light from a subject on an imaging surface of the solid-state imaging device; and (c) a signal processing circuit that performs signal processing on a signal output from the solid-state imaging device.

### BRIEF DESCRIPTION OF DRAWINGS

FIG. 1 is a diagram illustrating an overall configuration of an electronic device according to a first embodiment of the present disclosure.

FIG. 2 is a diagram illustrating the overall configuration of a solid-state imaging device according to the first embodiment of the present disclosure.

FIG. 3A is a diagram illustrating a cross-sectional configuration of a pixel array unit along line A-A in FIG. 2.

FIG. 3B is a diagram illustrating a minimum unit array of a color filter along line B-B in FIG. 3A.

FIG. 4 is a diagram illustrating the minimum unit array of a color filter acct a modification example.

FIG. 5 is a diagram illustrating a configuration of the color filter array.

FIG. 6 is a diagram illustrating the transmittance of each pixel of a solid-state imaging device in the related art.

FIG. 7 is a diagram illustrating the transmittance of each pixel of a solid-state imaging device according to a first embodiment.

FIG. 8 is a diagram illustrating the transmittance of each pixel of the solid-state imaging device according to the first embodiment.

FIG. 9 is a diagram illustrating the transmittance of each pixel of the solid-state imaging device according to the first embodiment.

FIG. 10 is a diagram illustrating the arrangement of microlenses according to a modification example.

FIG. 11 is a diagram illustrating the arrangement of microlenses according to a modification example.

FIG. 12 is a diagram illustrating a captured image generated by a signal processing circuit.

FIG. 13 is a diagram illustrating pixels used for estimation of a color temperature when the color temperature is low.

FIG. 14 is a diagram illustrating pixels used for estimation of a color temperature when the color temperature is flat.

FIG. 15 is a diagram illustrating pixels used for estimation of a color temperature when the color temperature is high.

FIG. 16 is a diagram illustrating the processing content of the re-mosaic processing.

FIG. 17 is a diagram illustrating the processing content of the binning processing.

FIG. 18 is a diagram illustrating a configuration of a color filter array of the solid-state image sensor according to the second embodiment of the present disclosure.

FIG. 19 is a diagram illustrating the minimum unit array of a color filter.

FIG. 20 is a diagram illustrating the processing content of the binning processing.

FIG. 21 is a diagram illustrating the processing content of the binning processing.

FIG. 22 is a diagram illustrating a configuration of a color filter array according to a modification example.

FIG. 23 is a diagram illustrating a configuration of a color filter array according to a modification example.

FIG. 24 is a block diagram illustrating an example of a schematic configuration of a vehicle control system.

FIG. 25 is an explanatory diagram illustrating an example of installation positions of an external information detection unit and an imaging unit.

FIG. 26 is a diagram illustrating an example of a schematic configuration of an endoscopic surgery system.

FIG. 27 is a block diagram illustrating an example of a functional configuration of a camera head and a CCU.

### DESCRIPTION OF EMBODIMENTS

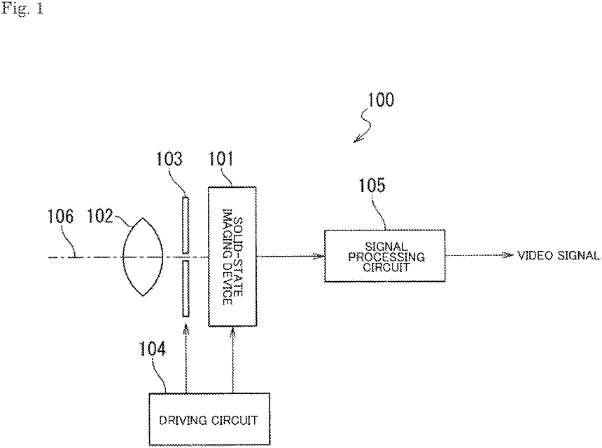

Hereinafter, examples of a solid-state imaging device 1 and electronic device according to an embodiment of the present disclosure will be described with reference to FIGS. 1 to 27. The embodiment of the present disclosure will be described in the following order. Note, however, that the present disclosure is not limited to the following examples. In addition, the effects described in this specification are exemplary and not limiting, and other effects may be provided.
1. First Embodiment: Electronic Device
1-1 Overall Configuration of Electronic Device
1-2 Configurations of Main Parts
2. Second Embodiment: Electronic Device
2-1 Configurations of Main Parts
2-2 Modification Example
3. Application Example to Moving Body
4. Application Example to Endoscopic Surgery System

### 1. First Embodiment: Electronic Device

### 1-1 Overall Configuration Example of Electronic Device

Next, an electronic device 100 according to a first embodiment of the present disclosure will be described. As the electronic device 100, various electronic devices, for example, an imaging device such as a digital still camera and a digital video camera, a mobile phone having an imaging function, or another device having an imaging function can be adopted. FIG. 1 is a schematic diagram illustrating an overall configuration of the electronic device 100 according to the first embodiment of the present disclosure.

As illustrated in FIG. 1, the electronic device 100 includes a solid-state imaging device 101 (hereinafter referred to as a “solid-state imaging device 1”), an optical lens 102, a shutter device 103, a driving circuit 104, and a signal processing circuit 105. In the electronic device 100, the optical lens 102 forms image light (incident light 106) from the subject on the imaging surface of the solid-state imaging device 101. The solid-state imaging device 101 converts the amount of the incident light 106 in pixel units into an electrical signal and outputs a pixel signal. The signal processing circuit 105 performs signal processing on the pixel signal output from the solid-state imaging device 101. In that case, the shutter device 103 controls a light irradiation period and a light shielding period for the solid-state imaging device 101. The driving circuit 104 supplies a driving signal for controlling an pixel signal transfer operation and a shutter operation of the shutter device 103.

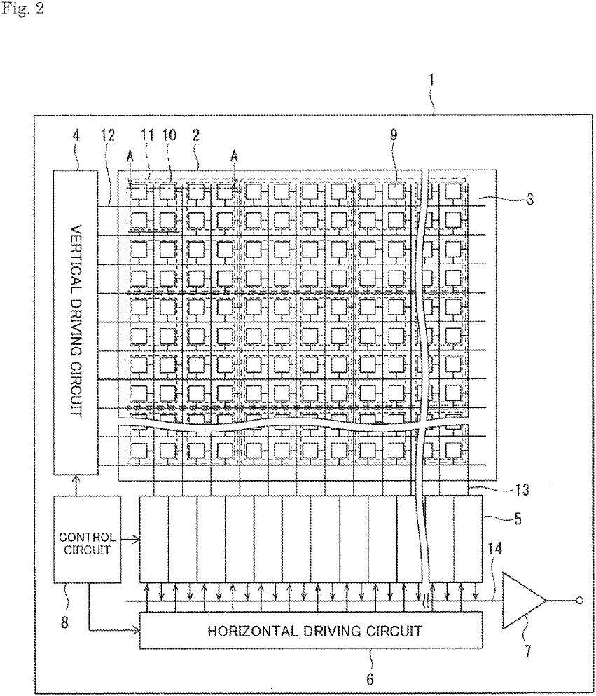

FIG. 2 is a schematic diagram illustrating the solid-state imaging device 1. The solid-state imaging device 1 in FIG. 2 is a backside irradiation type complementary metal oxide semiconductor (CMOS) image sensor. As illustrated in FIG. 2, the solid-state imaging device 1 includes a substrate 2, a pixel array unit 3, a vertical driving circuit 4, column signal processing circuits 5, a horizontal driving circuit 6, an output circuit 7, and a control circuit 8.

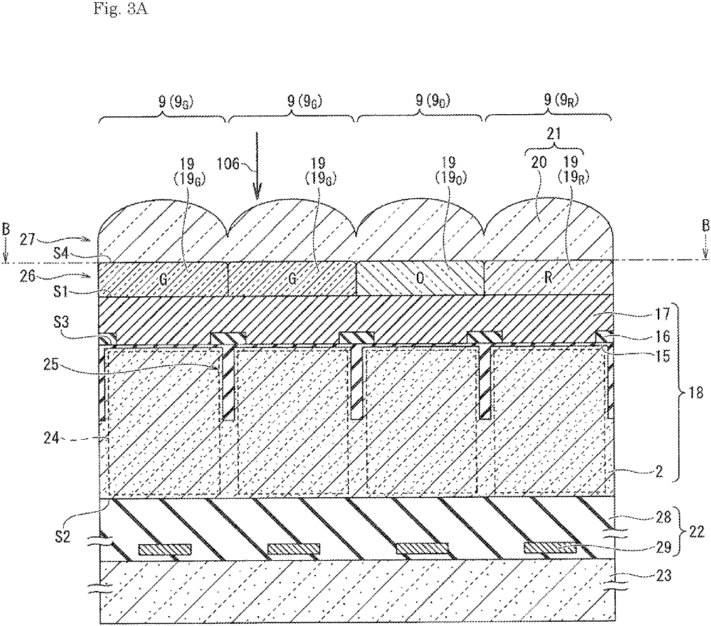

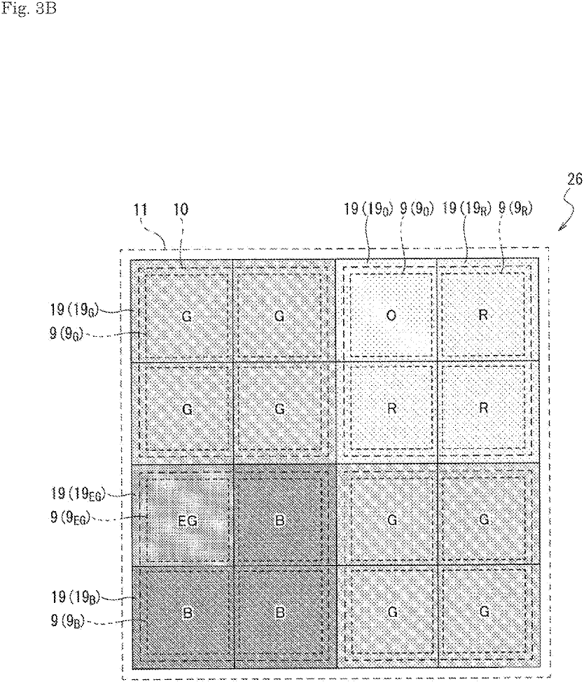

The pixel array unit 3 includes a plurality of pixels 9 arranged in a matrix on the substrate 2. As shown in FIGS. 3A and 3B, each of the pixels 9 has the photoelectric conversion unit 24 and a color filter 19 and a microlens 20 formed corresponding to the photoelectric conversion unit 24. Four pixels 9 arranged in a 2×2 matrix form one pixel unit 10. Further, four pixel units 10 arranged in a 2×2 matrix form one pixel unit group 11. That is, a plurality of pixel unit groups 11 arranged in a matrix forms a pixel array unit 3.

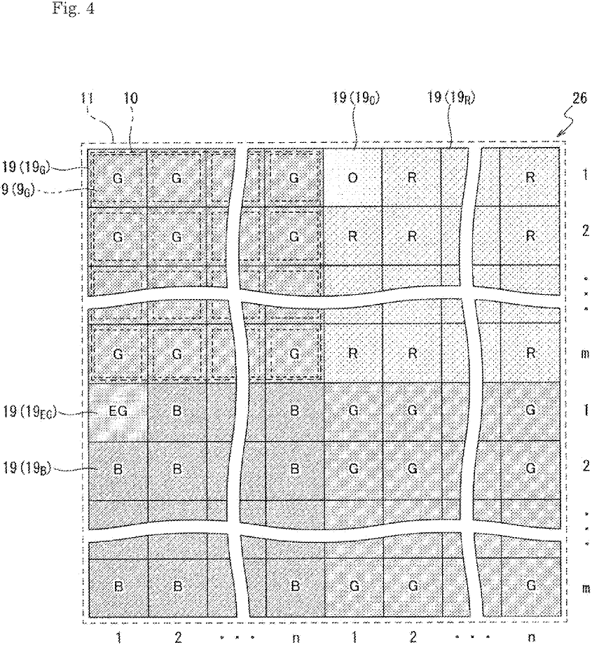

In the first embodiment, an example in which one pixel unit 10 is composed of pixels 9 arranged in a 2×2 matrix is shown, but other configurations can also be adopted. For example, as shown in FIG. 4, the pixels 9 may be arranged in a matrix of ₘ×ₙ (m and n are natural numbers of 2 or more). FIG. 4 illustrates a case where m and n are 5 or more.

The vertical driving circuit 4, which is constituted by, for example, a shift register, selects a desired pixel driving wiring 12, supplies a pulse for driving the pixels 9 to the selected pixel driving wiring 12, and drives the pixels 9 in units of rows. That is, the vertical driving circuit 4 sequentially performs selection scanning on the pixels 9 in the pixel array unit 3 in the vertical direction in units of rows, and supplies a pixel signal based on signal charges generated in accordance with the amount of light received in the photoelectric conversion unit 24 of each of the pixels 9 to the column signal processing circuits 5 through vertical signal lines 13.

The column signal processing circuit 5 is disposed, for example, for each column of the pixel 9, and performs signal processing such as noise removal for each pixel column on a signal which is output from the pixels 9 corresponding to one row. For example, the column signal processing circuit 5 performs signal processing such as correlated double sampling (CDS) and analog digital (AD) conversion for removing pixel-specific fixed pattern noise.

The horizontal driving circuit 6, which is constituted by, for example, a shift register, sequentially outputs a horizontal scanning pulse to the column signal processing circuits 5 to select each of the column signal processing circuits 5 in order, and outputs a pixel signal (hereinafter also referred to as a “pixel value”) having been subjected to signal processing to the horizontal signal line 14 from each of the column signal processing circuits 5.

The output circuit 7 performs signal processing on pixel signals (pixel values) sequentially supplied and outputs the pixel signals through the horizontal signal line 14 from each of the column signal processing circuits 5. As the signal processing, buffering, black level adjustment, column variation correction, and various types of digital signal processing can be adopted, for example.

The control circuit 8 generates a clock signal or a control signal as a reference for operations of the vertical driving circuit 4, the column signal processing circuit 5, the horizontal driving circuit 6, and the like on the basis of a vertical synchronization signal, a horizontal synchronization signal, and a master clock signal. In addition, the control circuit 8 outputs the generated clock signal or control signal to the vertical driving circuit 4, the column signal processing circuit 5, the horizontal driving circuit 6, and the like.

### 2 Configurations of Main Parts]

Next, a detailed configuration of the solid-state imaging device 1 in FIG. 1 will be described. FIG. 3A is a diagram illustrating a cross-sectional configuration of the pixel array unit 3 of the solid-state imaging device 1. FIG. 3B is a diagram illustrating the minimum unit array of the color filter 19 along line B-B in FIG. 3A. In FIGS. 3A and 3B, a backside irradiation type CMOS image sensor is used as the solid-state imaging device 1.

As illustrated in FIGS. 3A and 3B, the solid-state imaging device 1 according to the first embodiment includes a light receiving layer 18 in which the substrate 2, an insulating film 15, a light shielding film 16, and a planarization film 17 are laminated in this order. In addition, a light collecting layer 21 in which a color filter 19 and a microlens 20 (an on-chip lens) are laminated in this order is formed on a surface of the light receiving layer 18 on the insulating film 15 side (hereinafter, also referred to as a “rear surface S1”). Further, a wiring layer 22 and a supporting substrate 23 are laminated in this order on a surface of the light receiving layer 18 on the substrate 2 side (hereinafter, also referred to as a “surface S2”). Meanwhile, the rear surface S1 of the light receiving layer 18 and the rear surface of the planarization film 17 are the same surface, and thus the rear surface of the planarization film 17 will be referred to as a “rear surface S1” in the following description. In addition, the surface S2 of the light receiving layer 18 and the surface of the substrate 2 are the same surface, and thus the surface of the substrate 2 will be referred to as a “surface S2” in the following description.

The substrate 2 is constituted by a semiconductor substrate formed of, for example, silicon (Si), and forms the pixel array unit 3 illustrated in FIG. 1. In the pixel array unit 3, a plurality of photoelectric conversion units 24 formed on the substrate 2 are arranged in a matrix. In the photoelectric conversion unit 24, signal charges corresponding to the amount of incident light 106 are generated and accumulated. Further, a pixel separation unit 25 is arranged between adjacent photoelectric conversion units 24 so that the light transmitted through the other photoelectric conversion units 24 does not enter.

The insulating film 15 continuously covers the entire substrate 2 on the rear surface S1 side (the entirety on a light receiving surface side). In addition, the light shielding film 16 is formed in a lattice shape in a portion of the insulating film 15 on the rear surface S3 side (a portion on a light receiving surface side) so that a light receiving surface of each of the plurality of photoelectric conversion units 24 is open.

The color filter 19 is formed to correspond to each of the photoelectric conversion units 24 on the rear surface S1 side (light receiving surface side) of the insulating film 15. That is, one color filter 19 is formed for one photoelectric conversion unit 24 (pixel 9). In this way, the color filters 19 form color filter arrays 26 that are regularly arranged in a matrix. Each of the color filters 19 is configured to transmit light of a specific wavelength (red light, green light, blue light, orange light, emerald green light) of the incident light 106, and cause the transmitted light to be incident on the photoelectric conversion unit 24. As the color filter 19, an R-filter 19_{R} that transmits red light, a G-filter 19_{G} that transmits green light, a B-filter 19_{B} that transmits blue light, a predetermined color filter that transmits orange light (hereinafter, also referred to as “O-filter 19₀”), and a predetermined color filter (hereinafter, also referred to as “EG-filter 19_{EG}”) that transmits emerald green light are used.

In FIGS. 3A and 3B, reference numeral R indicates R-filters 19_{R}, reference numeral G indicates G-filters 19_{G}, reference numeral B indicates B-filters 19_{B}, reference numeral O indicates O-filters 19₀, and reference numeral EG indicates EG-filters 19_{EG}. Further, in the following description, the pixel 9 including the R-filter 19_{R} is referred to as a red pixel 9_{R}, the pixel 9 including the G-filter 19_{G} is referred to as a green pixel 9_{G}, the pixel 9 including the B-filter 19_{B} is referred to as a blue pixel 9_{B}, the pixel 9 including the O-filter 19₀ is referred to as an orange pixel 9o, and the pixel 9 including the EG-filter 19_{EG} is referred to as an emerald green pixel 9_{EG}.

As the transmittance peak wavelength of the O-filter 19₀, a numerical value within a first range, which is larger than the transmittance peak wavelength of the B-filter 19_{B} and less than the transmittance peak wavelength of the G-filter 19_{G}, is used. Further, as the transmittance peak wavelength of the EG-filter 19_{EG}, a numerical value within a second range, which is larger than the transmittance peak wavelength of the G-filter 19_{G} and less than the transmittance peak wavelength of the R-filter 19_{R}, is used. For example, when the transmittance peak wavelength of the R-filter 19_{R} is 600 nm, the transmittance peak wavelength of the G-filter 19_{G} is 530 nm, and the transmittance peak wavelength of the B-filter 19_{B} is 460 nm, it is preferable that the first range is larger than 465 nm and less than 525 nm and the second range is larger than 535 nm and less than 595 nm. In this way, the first range and the second range can be separated by 5 nm or more from the transmittance peak wavelengths of the R-filter 19_{R}, the G-filter 19_{G}, and the B-filter 19_{B}.

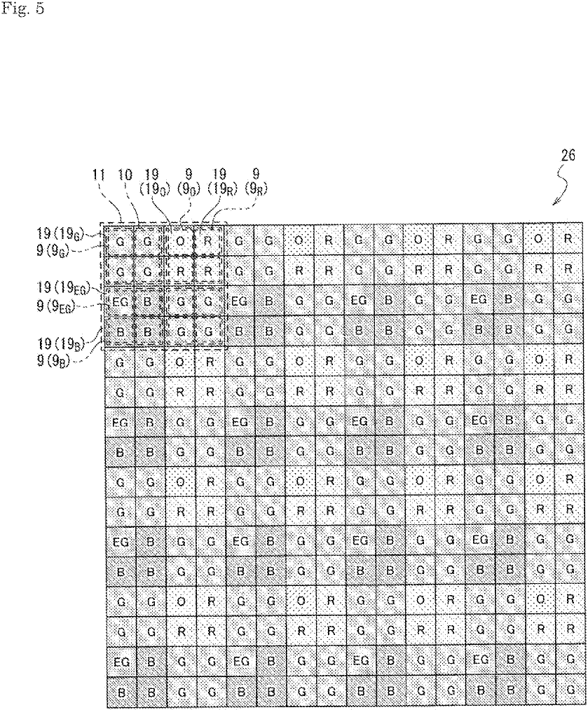

Further, the array pattern of the color filters 19 (the array pattern of the R-filter 19_{R}, the G-filter 19_{G}, the B-filter 19_{B}, the O-filter 19₀, and the EG-filter 19_{EG}) is configured such that the array of the color filters 19 arranged in a 4×4 matrix as shown in FIG. 3B is used as the minimum unit of the array of the color filters 19 (hereinafter, also referred to as “minimum unit array”), and the minimum unit arrays are arranged in all pixel unit groups 11 of the pixel array unit 3 as shown in FIG. 5.

As shown in FIG. 3B, the minimum unit array of the color filters 19 is an array in which the 4-division Bayer array is partially modified such that, among the four pixel units 10 constituting the pixel unit group 11, the R-filter 19_{R} is arranged on the upper-right pixel unit 10, the G-filter 19_{G} is arranged on the upper-left and lower-right pixel units 10, and the B-filter 19_{B} is arranged on the lower-left pixel unit 10. Specifically, the R-filter 19_{R} of the upper-left pixel 9 among the 2×2 pixels 9 constituting the upper-right pixel unit 10 of the 4-division Bayer array is replaced with the O-filter 19₀, and the B-filter 19_{B} of the upper-left pixel 9 among the 2×2 pixels 9 constituting the lower-left pixel unit 10 is replaced with the EG-filter 19_{EG}.

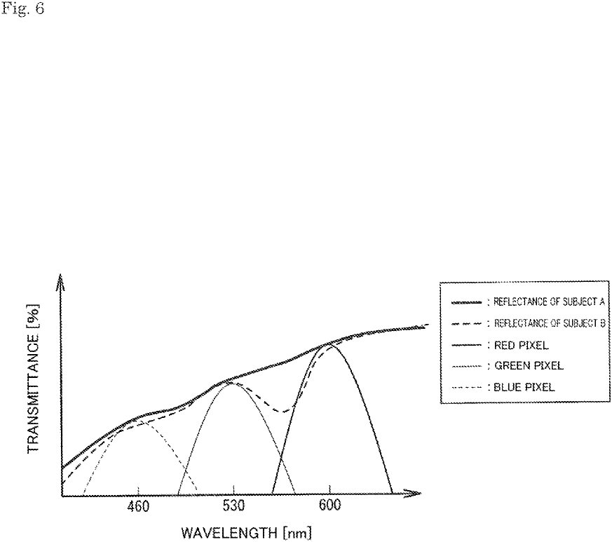

Here, for example, in a conventional solid-state imaging device including only the R-filter 19_{R}, the G-filter 19_{G}, and the B-filter 19_{B} as the color filter 19, light of the wavelengths (hereinafter also referred to as “outside peak wavelengths”) deviating from the transmittance peak wavelengths of the R-filter 19_{R}, the G-filter 19_{G}, and the B-filter 19_{B} hardly reaches the photoelectric conversion unit 24 and is not detected by the red pixel 9_{R}, the green pixel 9_{G}, and the blue pixel 9_{B}. Therefore, as shown in FIG. 6, when there are two subjects A and B having different reflectances at the outside peak wavelengths, the difference in color between the subjects A and B cannot be quantified. Therefore, in the conventional solid-state imaging device, the subjects A and B are determined as the same color.

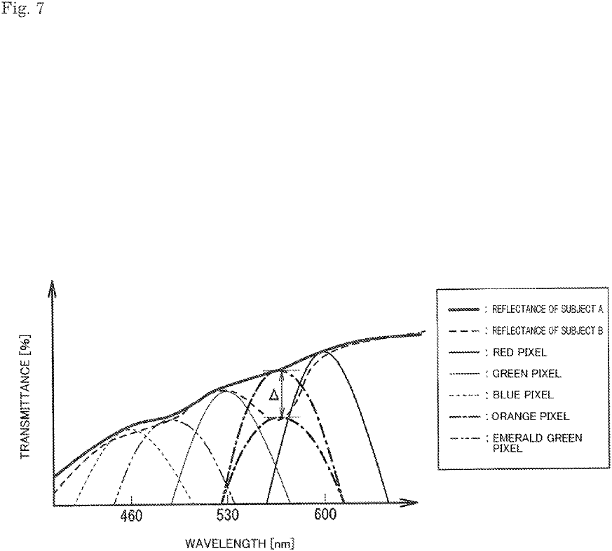

On the other hand, like the solid-state imaging device 1 according to the first embodiment, when the color filters 19 includes an O-filter 19₀ and an EG-filter 19_{EG} in addition to the R-filter 19_{R}, the G-filter 19_{G} and the B-filter 19_{B}, light having a wavelength between the transmittance peak wavelength of the R-filter 19_{R} and the transmittance peak wavelength of the G-filter 19_{G} passes through the EG-filter 19_{EG} and is detected by the emerald green pixel 9_{EG}. Further, light having a wavelength between the transmittance peak wavelength of the G-filter 19_{G} and the transmittance peak wavelength of the B-filter 19_{B} passes through the O-filter 19₀ and is detected by the orange pixel 9₀. That is, the sampling points of the incident light 106 can be increased by the configuration including the O-filter 19₀ and the EG-filter 19_{EG}. Therefore, as shown in FIG. 7, when there are two subjects A and B having different reflectances of the outside peak wavelengths, a difference Δ in color between the subjects A and B can be quantified. Therefore, in the solid-state imaging device 1 according to the first embodiment, the subjects A and B can be determined as different colors.

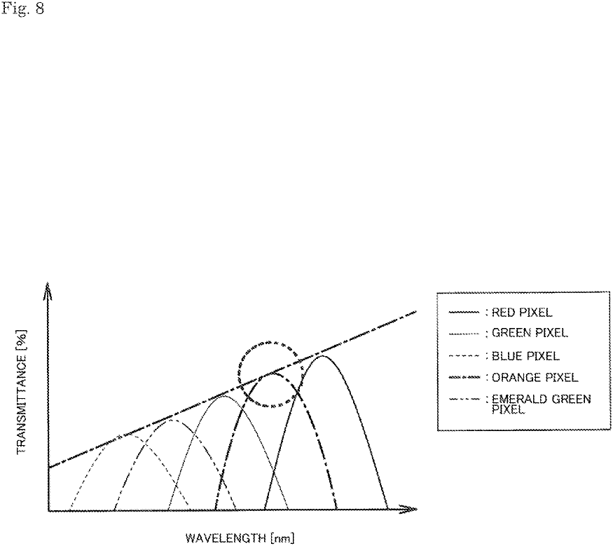

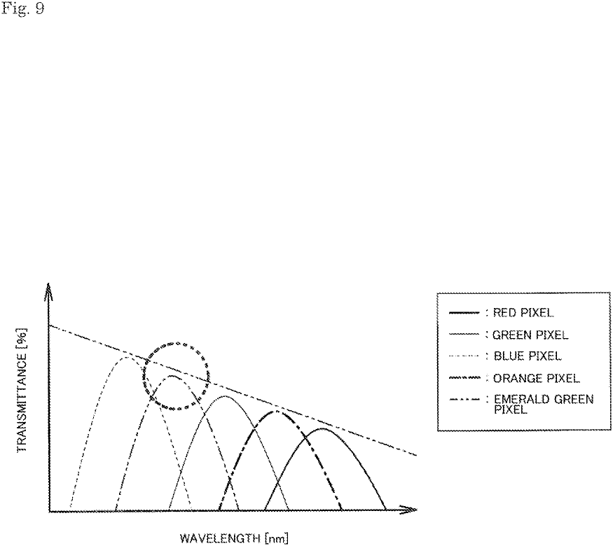

Therefore, when the pixel signals of the orange pixel 9₀ and the emerald green pixel 9_{EG} are used for estimating the color temperature in addition to the pixel signals of the red pixel 9_{R}, the green pixel 9_{G}, and the blue pixel 9_{B}, the color temperature of the light source can be estimated with higher accuracy. Therefore, the color reproducibility of the captured image can be improved by adjusting the white balance of the captured image based on the color temperature. For example, when the color temperature of the light source is low, the image light (incident light 106) from the subject contains a large amount of light having a long wavelength. However, as shown in FIG. 8, since the number of sampling points (points circled by the dotted line in FIG. 8) on the long wavelength side increases in the orange pixel 9o, the color reproducibility of the captured image can be improved. Further, for example, when the color temperature is high, as shown in FIG. 9, the incident light 106 from the subject contains a large amount of light having a short wavelength. However, since the number of sampling points (points circled by the dotted line in FIG. 9) on the short wavelength side increased in the emerald green pixel 9_{EG}, the color reproducibility of the captured image can be improved.

In the first embodiment, the example in which the G-filter 19_{G} is arranged in the upper-left and lower-right pixel units 10 is shown, but other configurations can also be adopted. For example, a configuration in which the G-filter 19_{G} is arranged in the upper-right and lower-left pixel units 10, a configuration in which the G-filter 19_{G} is arranged in the upper-left and lower-left pixel units 10, and a configuration in which the G-filter 19_{G} is arranged in the upper-right and lower-right pixel units 10 can also be adopted. Further, for example, a configuration in which the R-filter 19_{R} is arranged in the lower pixel unit 10 and the B-filter 19_{B} is arranged in the upper pixel unit 10 can also be adopted. That is, each of the pixel unit groups 11 may be configured such that, among the four pixel units 10 constituting the pixel unit group 11, one pixel unit 10 includes the R-filter 19_{R} as the color filter 19, two pixel units 10 include the G-filter 19_{G} as the color filter 19, one pixel unit 10 includes the B-filter 19_{B} as the color filter 19.

Further, in the first embodiment, an example in which all the pixel unit groups 11 of the pixel array unit 3 include the O-filter 19₀ and the EG-filter 19_{EG} is shown, but other configurations can also be adopted. For example, at least one of the pixel unit groups 11 constituting the pixel array unit 3 may be configured to include the O-filter 19₀ and the EG-filter 19_{EG} (predetermined color filter).

Further, in the first embodiment, an example in which the O-filter 19₀ and the EG-filter 19_{EG} are used as the color filter 19 (predetermined color filter) arranged together with the R-filter 19_{R}, the G-filter 19_{G}, and the B-filter 19_{B} is shown, other configurations can also be adopted. For example, as the predetermined color filter, a color filter 19 having a peak wavelength with a transmittance different from that of the R-filter 19_{R}, the G-filter 19_{G}, and the B-filter 19_{B} may be used.

Further, in the first embodiment, an example in which the R-filter 19_{R} of the upper-left pixel 9 among the 2×2 pixels 9 constituting the pixel unit 10 including the R-filter 19_{R} is replaced with the O-filter 19₀ is shown, other configurations can also be adopted. For example, any one of the R-filters 19_{R} of the lower-left pixel 9, the upper-right pixel 9, and the lower-right pixel 9 among the 2×2 pixels 9 may be replaced with the O-filter 19_{O}. Further, for example, the G-filter 19_{G} of any one of the 2×2 pixels 9 constituting the pixel unit 10 including the G-filter 19_{G} may be replaced with the O-filter 19_{O}. Further, for example, the B-filter 19_{B} of any one of the 2×2 pixels 9 constituting the pixel unit 10 including the B-filter 19_{B} may be replaced with the O-filter 19_{O}. In particular, it is more preferable that the O-filter 19_{O} (predetermined color filter) is included in the pixel unit 10 including the R-filter 19_{R} or the B-filter 19_{B}. Further, it is more preferable that the EG-filter 19_{EG} (predetermined color filter) is included in the pixel unit 10 including the R-filter 19_{R} or the B-filter 19_{B}, similarly to the O-filter 19_{O}. With such a configuration, the green pixel 9_{G} can be used as a pixel for acquiring luminance information and resolution information, and further as a phase difference pixel.

Further, in the first embodiment, an example in which the number of types of the color filters 19 included in one pixel unit 10 is one of the two types of the R-filter 19_{R} and the O-filter 19_{O} and the two types of the B-filter 19_{B} and the EG-filter 19_{EG} is shown, other configurations can also be adopted. For example, one pixel unit 10 may include only one type of the R-filter 19_{R}, the G-filter 19_{G}, and the B-filter 19_{B}, or may include the three types. In particular, a configuration in which the number of types of the color filters 19 included in one pixel unit 10 is 2 or less is more preferable. With such a configuration, it is possible to suppress a decrease in the area occupied by the red pixel 9_{R}, the green pixel 9_{G}, and the blue pixel 9_{B}.

The microlens 20 is formed to correspond to each of the photoelectric conversion units 24 on the rear surface S4 side (light receiving surface side) of the color filter 19. That is, one microlens 20 is formed for one photoelectric conversion unit 24 (pixel 9). In this way, the microlenses 20 form microlens arrays 27 that are regularly arranged in a matrix. Each of the microlenses 20 is configured to collect image light (incident light 106) from a subject and guide the collected incident light 106 to the vicinity of the rear surface (light receiving surface) of the photoelectric conversion unit 24 through the color filter 19.

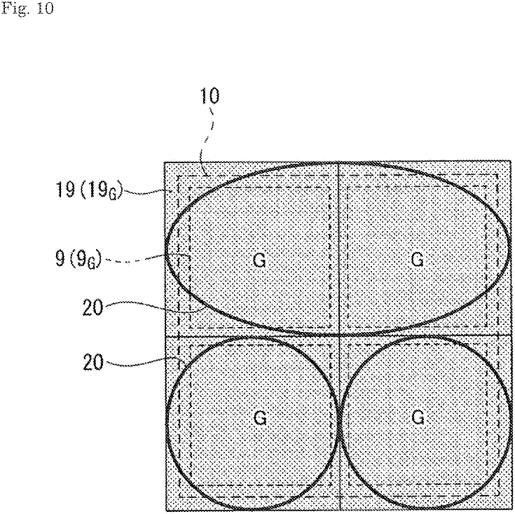

In the first embodiment, an example in which one microlens 20 is formed for one photoelectric conversion unit 24 is shown, but other configurations can also be adopted. For example, when the green pixel 9_{G} is used as the phase difference pixel, as shown in FIG. 10, two green pixels 9_{G} arranged in a 1×2 matrix may be used as the phase difference pixels, and one microlens 20 may be formed for the two green pixels 9_{G} (phase difference pixels). According to such a configuration, the phase difference of the captured image can be detected between the two green pixels 9_{G} (phase difference pixels) sharing one microlens 20.

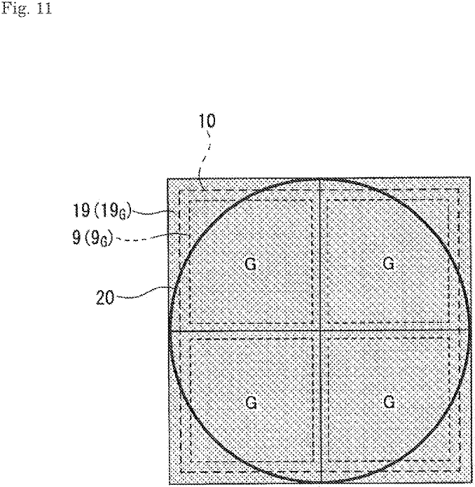

Further, for example, one microlens 20 may be formed for one pixel unit 10 (pixels 9 arranged in a 2×2 matrix). In this case, as shown in FIG. 11, for example, when the green pixel 9_{G} is used as the phase difference pixel, the four green pixels 9_{G} arranged in a 2×2 matrix are used as the phase difference pixels, and one microlens 20 is formed for the four green pixels 9_{G} (phase difference pixels). According to such a configuration, the phase difference of the captured image can be detected between the four green pixels 9_{G} (phase difference pixels) sharing one microlens 20.

The wiring layer 22 is formed on the surface S2 side of the substrate 2, and is configured to include an insulating interlayer film 28 and wirings 29 laminated as a plurality of layers with the insulating interlayer film 28 interposed therebetween. The wiring layer 22 drives a pixel transistor constituting the pixels 9 through the plurality of layers of wirings 29.

The supporting substrate 23 is formed on a surface of the wiring layer 22 opposite to a side facing the substrate 2. The supporting substrate 23 is a substrate for securing the strength of the substrate 2 at a manufacturing stage of the solid-state imaging device 1. As a material of the supporting substrate 23, for example, silicon (Si) can be used.

Next, the signal processing executed by the signal processing circuit 105 of FIG. 1 will be described.

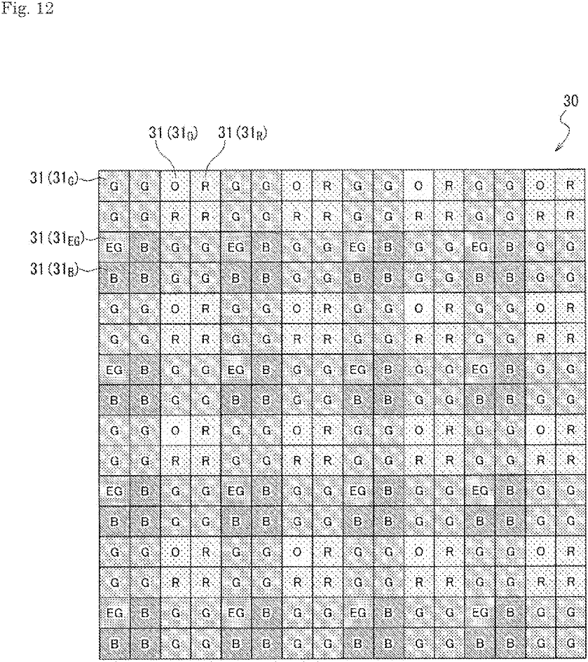

First, as shown in FIG. 12, for example, the signal processing circuit 105 performs a process of generating a mosaic image 30 corresponding the array of the color filters 19 based on the pixel signals (pixel values) output from the red pixel 9_{R}, the green pixel 9_{G}, the blue pixel 9_{B}, the orange pixel 9_{O}, and the emerald green pixel 9_{EG}. In FIG. 12, reference numeral R indicates an image pixel 31_{R} having only color information of red (hereinafter, also referred to as “red image pixel”), and similarly, reference numeral G indicates an image pixel 31_{G} having only color information of green (hereinafter, also referred to as “green image pixel”), reference numeral B indicates an image pixel 31_{B} having only color information of blue (hereinafter, also referred to as “blue image pixel”), reference numeral O indicates an image pixel 31_{O} having only color information of orange (hereinafter, also referred to as “orange image pixel”), and reference numeral EG indicates an image pixel 31_{EG} having only color information of emerald green (hereinafter, also referred to as “emerald green image pixel”).

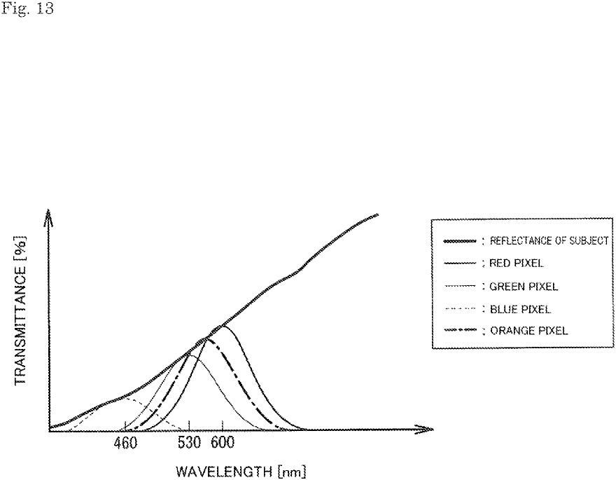

Subsequently, the signal processing circuit 105 performs a process of estimating the color temperature of the light source based on the pixel values (the pixel values of the red, green, blue, orange, and emerald green image pixels 31_{R}, 31_{G}, 31_{B}, 31_{O}, and 31_{EG}) of each image pixel of the generated mosaic image 30 and adjusting the white balance based on the estimated color temperature. In the estimation of the color temperature, when the color temperature of the light source is low, as shown in FIG. 13, the component on the long wavelength side of the reflectance of the subject increases, and the amount of light on the long wavelength side contained in the incident light 106 increases. Therefore, the color temperature is estimated using the pixel value of the orange image pixel 31_{O} in addition to the pixel values of the red, green, and blue image pixels 31_{R}, 31_{G}, and 31_{B} of the mosaic image 30.

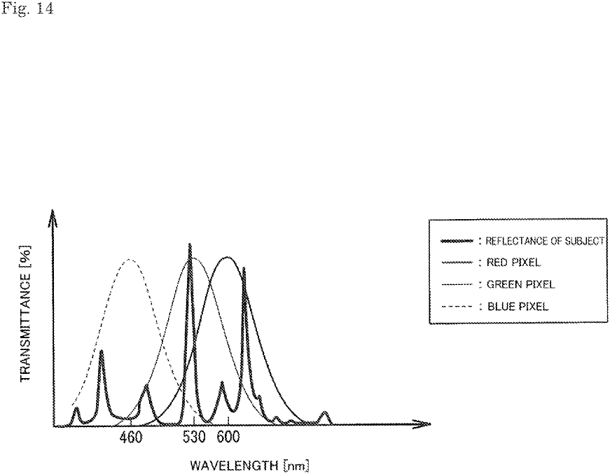

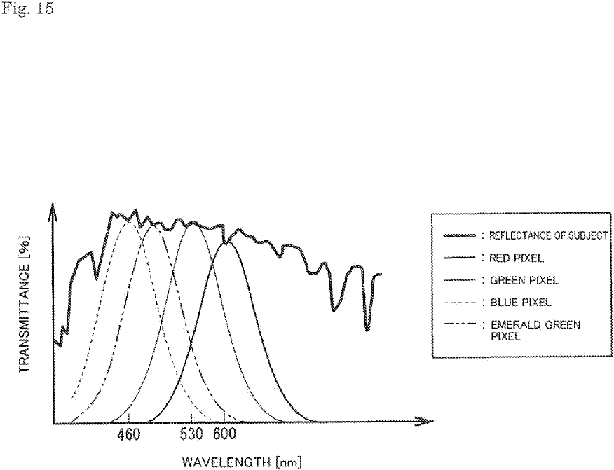

On the other hand, when the color temperature of the light source is flat, that is, when the reflectance of the subject is about the same at all wavelengths from the short wavelength side to the long wavelength side as shown in FIG. 14, the amount of light of each wavelength contained in the incident light 106 is about the same. Therefore, the color temperature is estimated using only only the pixel values of the red, green, and blue image pixels 31_{R}, 31_{G}, and 31_{B} of the mosaic image 30. If necessary, the pixel values of the orange and emerald green image pixels 31_{O} and 31_{EG} may also be used for estimating the color temperature. On the other hand, when the color temperature of the light source is high, the component on the short wavelength side of the reflectance of the subject increases, and the amount of light on the short wavelength side contained in the incident light 106 increases. Therefore, as shown in FIG. 15, the color temperature is estimated using the pixel value of the emerald green image pixel 31_{EG} In addition to the pixel values of the red, green, and blue image pixels 31_{R}, 31_{G}, and 31_{B}.

In the first embodiment, an example in which the color temperature is estimated from the pixel value and the white balance is adjusted based on the estimation result is shown, but other configurations can also be adopted. For example, the white balance may be adjusted directly from the pixel value. Specifically, the pixel values S_{R}′(A), S_{G}′(A), S_{B}′(A), So′(A), and S_{EG}′(A) after white balance adjustment are calculated based on the pixel values S_{R}(A), S_{G}(A), S_{B}(A), So(A), and S_{EG}(A) of the red pixel 9_{R}, the green pixel 9_{G}, the blue pixel 9_{B}, the orange pixel 9_{O}, and the emerald green pixel 9_{EG} according to Formula (1) below.

$$\text{SR'} \left(\text{A}\right) = \text{Smax} \times \text{SR} \left(\text{A}\right) / \text{SR} \left(\text{W}\right)$$

$$\text{SG'} \left(\text{A}\right) = \text{Smax} \times \text{SG} \left(\text{A}\right) / \text{SG} \left(\text{W}\right)$$

$$\text{SB'} \left(\text{A}\right) = \text{Smax} \times \text{SB} \left(\text{A}\right) / \text{SB} \left(\text{W}\right)$$

$$\text{SO'} \left(\text{A}\right) = \text{Smax} \times \text{SO} \left(\text{A}\right) / \text{SO} \left(\text{W}\right)$$

$$\text{SEG'} \left(\text{A}\right) = \text{Smax} \times \text{SB} \left(\text{A}\right) / \text{SEG} \left(\text{W}\right)$$

In Formula (1), Smax is the maximum value of the pixel value (for example, 255 in the case of 8 bits and 1023 in the case of 10 bits), and S_{R}(W), S_{G}(W), S_{B}(W), So(W), and S_{EG}(W) are the pixel signals (pixel values) from the red pixel 9_{R}, the green pixel 9_{G}, the blue pixel 9_{B}, the orange pixel 9_{O}, and the emerald green pixel 9_{EG} at the time of imaging a white plate (standard white plate with 100% reflectance).

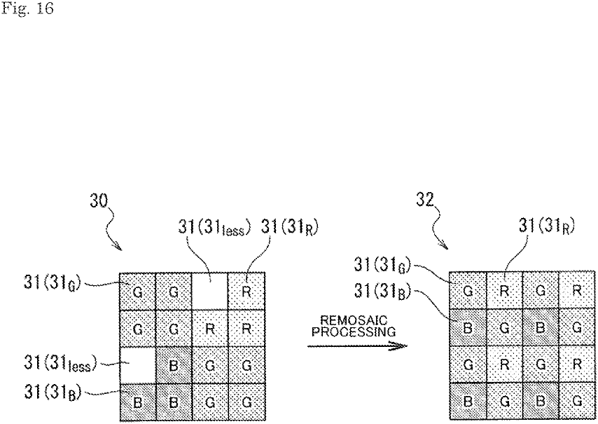

Subsequently, a process of determining whether the subject is bright is performed based on the pixel values of each image pixel 31 of the mosaic image 30. Then, when it is determined that the subject is bright, remosaic processing is performed on the mosaic image 30 whose white balance has been corrected. In the remosaic processing, as shown in FIG. 16, an RGB mosaic image 32 of the Bayer array is generated. When the remosaic processing is executed, the orange and emerald green image pixels 31_{O} and 31_{EG} are regarded as colorless image pixels 31ₗₑₛₛ, and the pixel values of the colorless image pixels 31ₗₑₛₛ are complemented using the pixel values of the surrounding image pixels 31. FIG. 16 shows a part of the mosaic image 30 and the RGB mosaic image 32 at an enlarged scale.

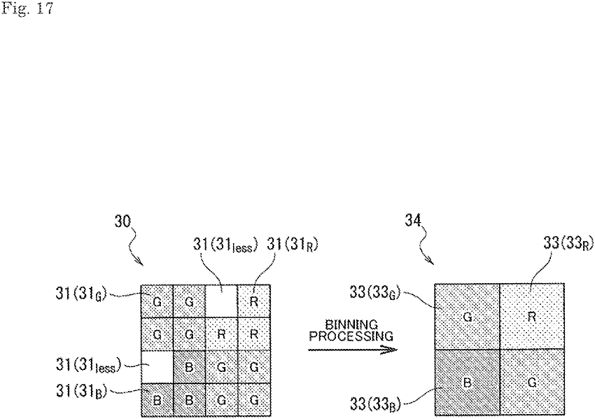

On the other hand, when it is determined that the subject is dark, binning processing is performed on the mosaic image 30 whose white balance has been corrected. In the binning processing, as shown in FIG. 17, the pixel values of a plurality of adjacent image pixels 31 of the same color are added to obtain a pixel value of one image pixel 31. When the binning processing is executed, as shown in FIG. 17, the orange image pixel 31_{O} is regarded as the colorless image pixel 31ₗₑₛₛ, and the pixel values of the three red image pixels 31_{R} excluding the colorless image pixel 31ₗₑₛₛ are added. Further, in the binning processing, the emerald green image pixel 31_{EG} is regarded as a colorless image pixel 31ₗₑₛₛ, and the pixel values of the three blue image pixels 31_{B} excluding the colorless image pixel 31ₗₑₛₛ are added. As a result, the RGB mosaic image 34 composed of the red, green and blue image pixels 33_{R}, 33_{G} and 33_{B} is generated. By performing the binning processing, the number of pixels of the RGB mosaic image 34 is reduced, but noise and the like during imaging in a dark place can be reduced.

Subsequently, demosaic processing is performed on the RGB mosaic image 32 (see FIG. 16) obtained by the remosaic processing or the RGB mosaic image 34 obtained by the binning processing. FIG. 17 shows a part of the mosaic image 30 and the RGB mosaic image 34 at an enlarged scale.

As described above, in the solid-state imaging device 1 according to the first embodiment of the present disclosure, the O-filter 19_{O} and the EG-filter 19_{EG} (predetermined color filter) having a transmittance peak wavelength different from any of the R-filter 19_{R}, the G-filter 19_{G}, and the B-filter 19_{B} are included in at least one of the pixel unit groups 11 as the color filter 19. Therefore, the color temperature of the light source can be estimated with higher accuracy. Therefore, it is possible to provide the solid-state imaging device 1 capable of improving the color reproducibility of the captured image by adjusting the white balance of the mosaic image 30 based on the color temperature.

Further, in the solid-state imaging device 1 according to the first embodiment of the present disclosure, the O-filter 19_{O} and the EG-filter 19_{EG} are included as the color filter 19 in each of the pixel unit groups 11. Therefore, all the pixel unit groups 11, that is, the pixel unit groups 11 of each part of the pixel array unit 3 can be used for adjusting the white balance, and the color reproducibility can be improved more appropriately.

### 2. Second Embodiment: Electronic Device

### 1 Configurations of Main Parts]

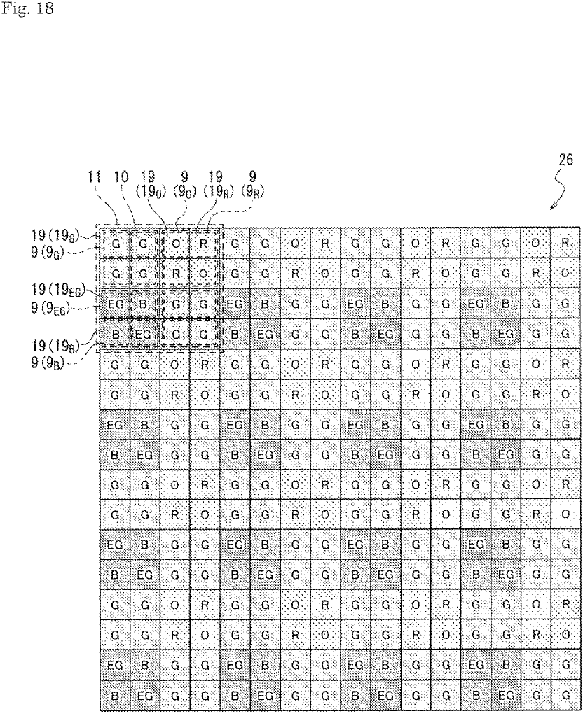

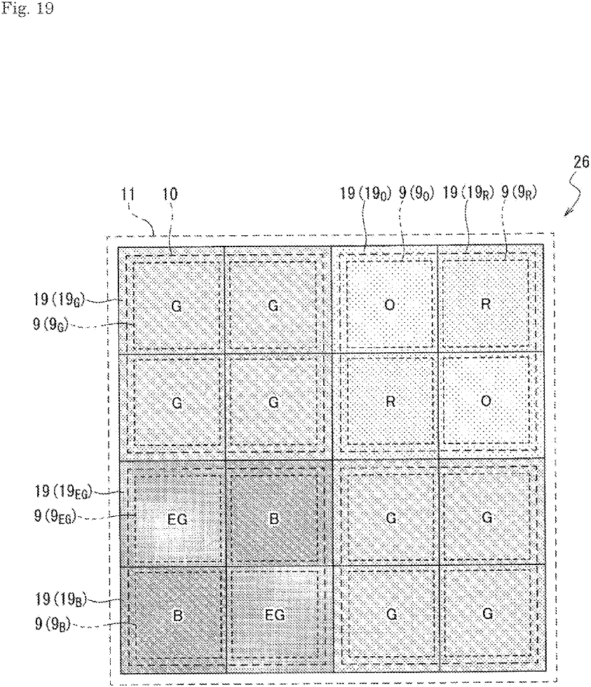

Next, the electronic device 100 according to a second embodiment of the present disclosure will be described. An overall configuration of the electronic device 100 according to the second embodiment is not shown because it is the same as in FIG. 1. FIG. 18 is a diagram illustrating a configuration of the color filter array 26 of the solid-state imaging device 1 according to the second embodiment. FIG. 19 is a diagram illustrating the minimum unit array of the color filter 19. In FIGS. 18 and 19, parts corresponding to those in FIG. 3B are given the same reference signs, and redundant descriptions thereof will not be given.

The solid-state imaging device 1 according to the second embodiment is different from the solid-state imaging device 1 according to the first embodiment in the arrangement of the O-filter 19₀ and the EG-filter 19_{EG}. In the solid-state imaging device 1 according to the second embodiment, as shown in FIGS. 18 and 19, the O-filter 19₀ is arranged in the upper-left and lower-right pixels 9 among the 2×2 pixels 9 constituting the upper-right pixel unit 10 in the minimum unit array of the color filters 19. Further, the EG-filter 19_{EG} is arranged in the upper-left and lower-right pixels 9 among the 2×2 pixels 9 constituting the lower-left pixel unit 10. That is, each of the upper-right pixel unit 10 and the lower-left pixel unit 10 includes the same type of predetermined color filter in the two pixels 9 of one pixel unit 10.

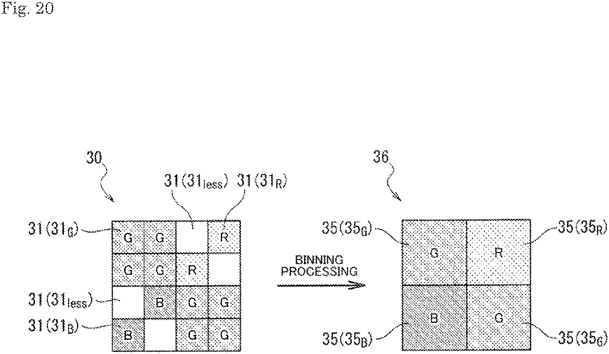

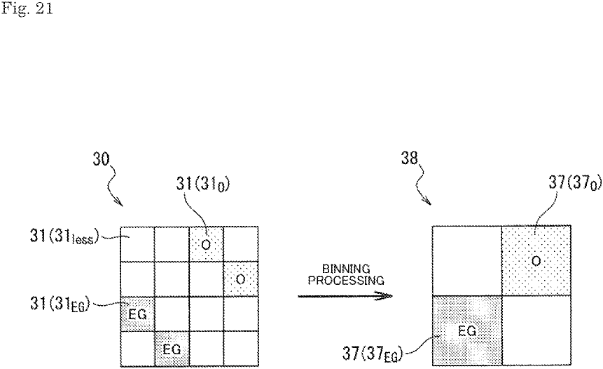

As described above, in the solid-state imaging device 1 according to the second embodiment of the present disclosure, each of the pixel units 10 including the O-filter 19₀ and the EG-filter 19_{EG} includes the same type of predetermined color filter in the two pixels 9 of one pixel unit 10. Therefore, as shown in FIGS. 20 and 21, by performing binning processing on the mosaic image 30 corresponding to the arrangement of the color filters 19, it is possible to generate a CMY mosaic image 38 composed of the image pixels 37₀ and 37_{EG} having only the color information of orange and emerald green in addition to the RGB mosaic image 36 composed of the image pixels 35_{R}, 35_{G}, and 35_{B} having only the color information of red, green, and blue. Further, by combining the RGB mosaic image 36 and the CMY mosaic image 38, it is possible to generate a captured image having higher color reproducibility. FIG. 20 shows a part of the mosaic image 30 and the RGB mosaic image 36 at an enlarged scale. Further, FIG. 21 shows a part of the mosaic image 30 and the CMY mosaic image 38 at an enlarged scale.

### 2 Modification Example]

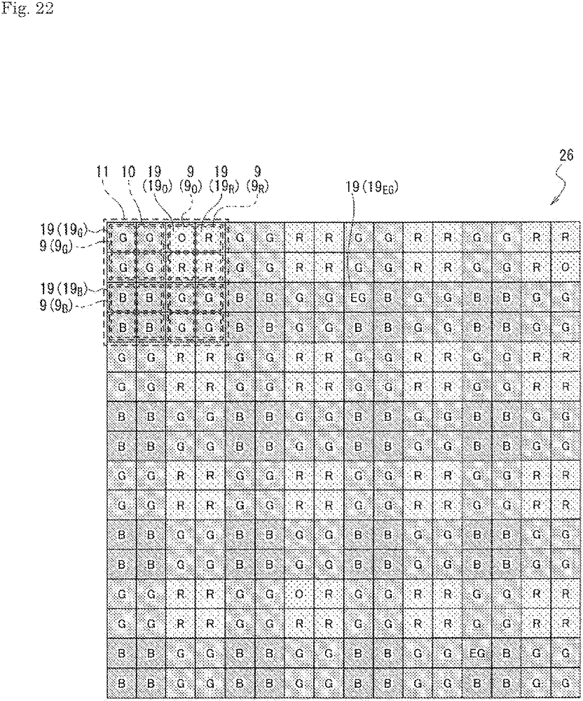

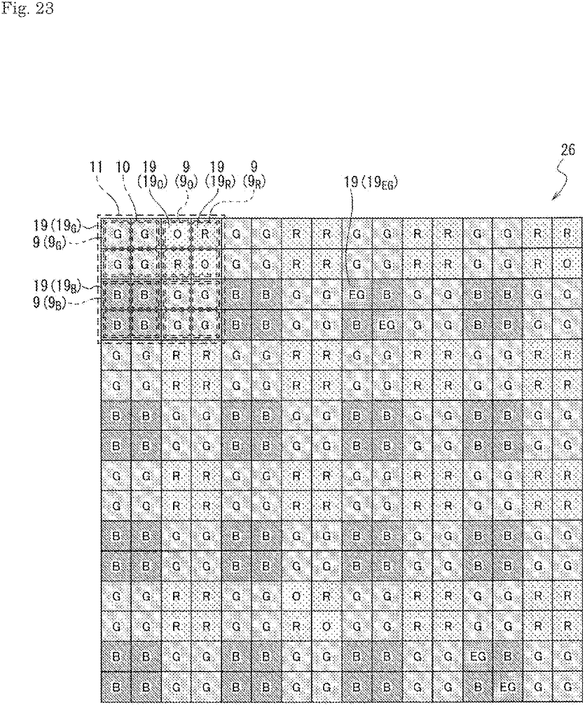

In the first embodiment and the second embodiment, an example in which the O-filter 19₀ and the EG-filter 19_{EG} (predetermined color filters) are included in each of all the pixel unit groups 11 of the pixel array unit 3 is shown, but other configurations can also be adopted. For example, as shown in FIGS. 22 and 23, the predetermined color filters may be included in only partial pixel unit groups 11 among all the pixel unit groups 11 of the pixel array unit 3. The number of “partial pixel unit groups 11” may be, for example, a number that can secure the SN (signal-to-noise) ratio required for estimating the color temperature of the light source.

FIGS. 22 and 23 illustrate a case where the O-filter 19₀ and the EG-filter 19_{EG} are arranged only in four pixel unit groups 11. In this example, only one of the O-filter 19₀ and the EG-filter 19_{EG} is arranged in one pixel unit group 11. FIG. 22 illustrates a case where it is applied to the solid-state imaging device 1 according to the first embodiment. FIG. 23 illustrates a case where it is applied to the solid-state imaging device 1 according to the second embodiment. By arranging the O-filter 19₀ and the EG-filter 19_{EG} only in a partial pixel unit group 11, it is possible to suppress the deterioration of other characteristics such as resolution and HDR while improving the color reproducibility.

### 3. Application Example to Moving Body

The technology (the present technology) according to the present disclosure can be applied to various products. For example, the technology according to the present disclosure may be realized as a device mounted in any type of moving body such as an automobile, an electric automobile, a motorbike, a hybrid electric automobile, a bicycle, a personal mobility, an airplane, a drone, a ship, and a robot.

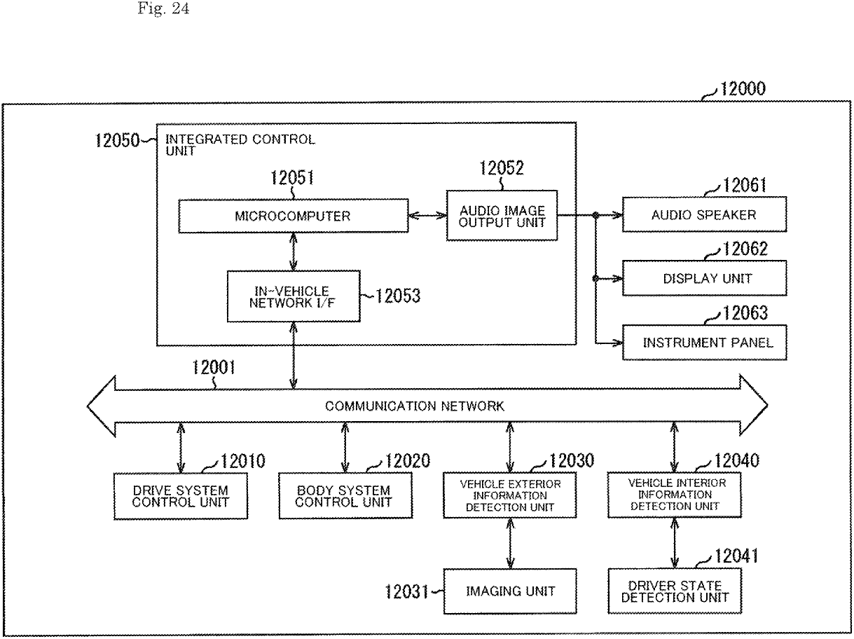

FIG. 24 is a block diagram illustrating a schematic configuration example of a vehicle control system that is an example of a moving body control system to which the technology according to the present disclosure can be applied.

The vehicle control system 12000 includes a plurality of electronic control units connected via a communication network 12001. In the example illustrated in FIG. 24, the vehicle control system 12000 includes a drive system control unit 12010, a body system control unit 12020, a vehicle exterior information detection unit 12030, a vehicle interior information detection unit 12040, and an integrated control unit 12050. In addition, as a functional configuration of the integrated control unit 12050, a microcomputer 12051, an audio image output unit 12052, and an in-vehicle network interface (I/F) 12053 are illustrated.

The drive system control unit 12010 controls operations of devices related to a drive system of a vehicle according to various programs. For example, the drive system control unit 12010 functions as a driving force generation device for generating a driving force of a vehicle such as an internal combustion engine or a driving motor, a driving force transmission mechanism for transmitting a driving force to wheels, a steering mechanism for adjusting a turning angle of a vehicle, and a control device such as a braking device that generates a braking force of a vehicle.

The body system control unit 12020 controls operations of various devices mounted in the vehicle body according to various programs. For example, the body system control unit 12020 functions as a control device such as a keyless entry system, a smart key system, a power window device, or various lamps such as a headlamp, a back lamp, a brake lamp, a turn signal and a fog lamp. In this case, radio waves transmitted from a portable device that substitutes for a key or signals of various switches may be input to the body system control unit 12020. The body system control unit 12020 receives inputs of the radio waves or signals, and controls a door lock device, a power window device, and a lamp of the vehicle.

The vehicle exterior information detection unit 12030 detects information outside the vehicle in which the vehicle control system 12000 is mounted. For example, an imaging unit 12031 is connected to the vehicle exterior information detection unit 12030. The vehicle exterior information detection unit 12030 causes the imaging unit 12031 to capture an image of the outside of the vehicle and receives the captured image. The vehicle exterior information detection unit 12030 may perform object detection processing or distance detection processing for peoples, cars, obstacles, signs, and letters on the road based on the received image.

The imaging unit 12031 is an optical sensor that receives light and outputs an electrical signal according to the amount of received light. The imaging unit 12031 can also output the electrical signal as an image and ranging information. In addition, the light received by the imaging unit 12031 may be visible light or invisible light such as infrared light.

The vehicle interior information detection unit 12040 detects information on the inside of the vehicle. For example, a driver state detection unit 12041 that detects a driver’s state is connected to the vehicle interior information detection unit 12040. The driver state detection unit 12041 includes, for example, a camera that captures an image of a driver, and the vehicle interior information detection unit 12040 may calculate a degree of fatigue or concentration of the driver or may determine whether or not the driver is dozing on the basis of detection information input from the driver state detection unit 12041.

The microcomputer 12051 can calculate a control target value of the driving force generation device, the steering mechanism, or the braking device on the basis of the information on the inside and the outside of the vehicle acquired by the vehicle exterior information detection unit 12030 or the vehicle interior information detection unit 12040, and output a control command to the drive system control unit 12010. For example, the microcomputer 12051 can perform cooperative control aiming at realizing functions of advanced driver assistance system (ADAS) including vehicle collision avoidance or impact mitigation, follow-up traveling based on an inter-vehicle distance, vehicle speed maintenance traveling, vehicle collision warning, vehicle lane deviation warning, and the like.

Further, the microcomputer 12051 can perform coordinated control for the purpose of automated driving or the like in which autonomous travel is performed without depending on operations of the driver by controlling the driving force generation device, the steering mechanism, the braking device, and the like on the basis of information regarding the surroundings of the vehicle acquired by the vehicle exterior information detection unit 12030 or the vehicle interior information detection unit 12040.

In addition, the microcomputer 12051 can output a control command to the body system control unit 12020 based on the information outside the vehicle acquired by the vehicle exterior information detection unit 12030. For example, the microcomputer 12051 can perform cooperative control for the purpose of preventing glare, such as switching from a high beam to a low beam, by controlling the headlamp according to the position of a preceding vehicle or an oncoming vehicle detected by the vehicle exterior information detection unit 12030.

The audio image output unit 12052 transmits an output signal of at least one of audio and an image to an output device capable of visually or audibly notifying an occupant of a vehicle or the outside of the vehicle of information. In the example shown in FIG. 24, as such an output device, an audio speaker 12061, a display unit 12062 and an instrument panel 12063 are shown. The display unit 12062 may include, for example, at least one of an onboard display and a head-up display.

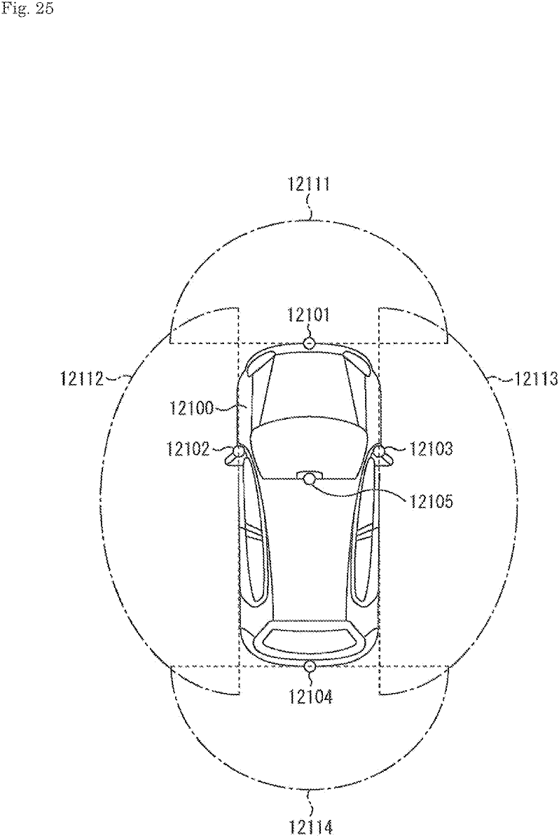

FIG. 25 is a diagram illustrating an example of an installation position of the imaging unit 12031.

In FIG. 25, a vehicle 12100 includes imaging units 12101, 12102, 12103, 12104, and 12105 as the imaging unit 12031.

The imaging units 12101, 12102, 12103, 12104, and 12105 may be provided at positions such as a front nose, side-view mirrors, a rear bumper, a back door, and an upper part of a windshield in a vehicle interior of the vehicle 12100, for example. The imaging unit 12101 provided on a front nose and the imaging unit 12105 provided in an upper portion of the vehicle interior front glass mainly acquire images of a side in front of the vehicle 12100. The imaging units 12102 and 12103 provided on the side mirrors mainly acquire images of sides of the vehicle 12100. The imaging unit 12104 provided on the rear bumper or the back door mainly acquires images of a side behind the vehicle 12100. The images of a front side which are acquired by the imaging units 12101 and 12105 are mainly used for detection of preceding vehicles, pedestrians, obstacles, traffic signals, traffic signs, lanes, and the like.

FIG. 25 shows an example of imaging ranges of the imaging units 12101 to 12104. An imaging range 12111 indicates an imaging range of the imaging unit 12101 provided at the front nose, imaging ranges 12112 and 12113 respectively indicate the imaging ranges of the imaging units 12102 and 12103 provided at the side mirrors, and an imaging range 12114 indicates the imaging range of the imaging unit 12104 provided at the rear bumper or the back door. For example, a bird’s-eye view image of the vehicle 12100 as viewed from above can be obtained by superimposition of image data captured by the imaging units 12101 to 12104.

At least one of the imaging units 12101 to 12104 may have a function for obtaining distance information. For example, at least one of the imaging units 12101 to 12104 may be a stereo camera constituted by a plurality of imaging elements or may be an imaging element that has pixels for phase difference detection.

For example, the microcomputer 12051 can extract, particularly, a closest three-dimensional object on a path through which the vehicle 12100 is traveling, which is a three-dimensional object traveling at a predetermined speed (for example, 0 km/h or higher) in the substantially same direction as the vehicle 12100, as a preceding vehicle by acquiring a distance to each of three-dimensional objects in the imaging ranges 12111 to 12114 and temporal change in the distance(a relative speed with respect to the vehicle 12100) on the basis of distance information obtained from the imaging units 12101 to 12104. Further, the microcomputer 12051 can set an inter-vehicle distance which should be guaranteed in advance in front of a preceding vehicle and can perform automated brake control(also including following stop control) or automated acceleration control(also including following start control). In this way, it is possible to perform cooperated control in order to perform automated driving or the like in which a vehicle autonomously travels irrespective of a manipulation of a driver.

For example, the microcomputer 12051 can classify and extract three-dimensional object data regarding three-dimensional objects into two-wheeled vehicles, ordinary vehicles, large vehicles, pedestrians, and other three-dimensional objects such as utility poles on the basis of distance information obtained from the imaging units 12101 to 12104 and use the three-dimensional object data for automatic avoidance of obstacles. For example, the microcomputer 12051 identifies obstacles in the vicinity of the vehicle 12100 into obstacles that can be visually recognized by the driver of the vehicle 12100 and obstacles that are difficult to visually recognize. Then, the microcomputer 12051 can determine a risk of collision indicating the degree of risk of collision with each obstacle, and can perform driving assistance for collision avoidance by outputting a warning to a driver through the audio speaker 12061 or the display unit 12062 and performing forced deceleration or avoidance steering through the drive system control unit 12010 when the risk of collision has a value equal to or greater than a set value and there is a possibility of collision.

At least one of the imaging units 12101 to 12104 may be an infrared camera that detects infrared rays. For example, the microcomputer 12051 can recognize a pedestrian by determining whether there is a pedestrian in the captured image of the imaging units 12101 to 12104. Such pedestrian recognition is performed by, for example, a procedure in which feature points in the captured images of the imaging units 12101 to 12104 as infrared cameras are extracted and a procedure in which pattern matching processing is performed on a series of feature points indicating the outline of the object and it is determined whether the object is a pedestrian. When the microcomputer 12051 determines that there is a pedestrian in the captured images of the imaging units 12101 to 12104, and the pedestrian is recognized, the audio image output unit 12052 controls the display unit 12062 so that the recognized pedestrian is superimposed and displayed with a square contour line for emphasis. In addition, the audio image output unit 12052 may control the display unit 12062 so that an icon indicating a pedestrian or the like is displayed at a desired position.

An example of the vehicle control system to which the technology according to the present disclosure is applied has been described above. The technology of the present disclosure can be applied to the imaging unit 12031 and the like in the above-described configuration. Specifically, the solid-state imaging devices 101 and 1 in FIGS. 1 and 2 and the signal processing circuit 105 in FIG. 1 can be applied to the imaging unit 12031. By applying the technique according to the present disclosure to the imaging unit 12031, a clearer captured image can be obtained, which makes it possible to reduce driver fatigue.

### 4. Application Example to Endoscopic Surgery System

The technology according to the present disclosure (the present technology) may be applied to, for example, an endoscopic surgery system.

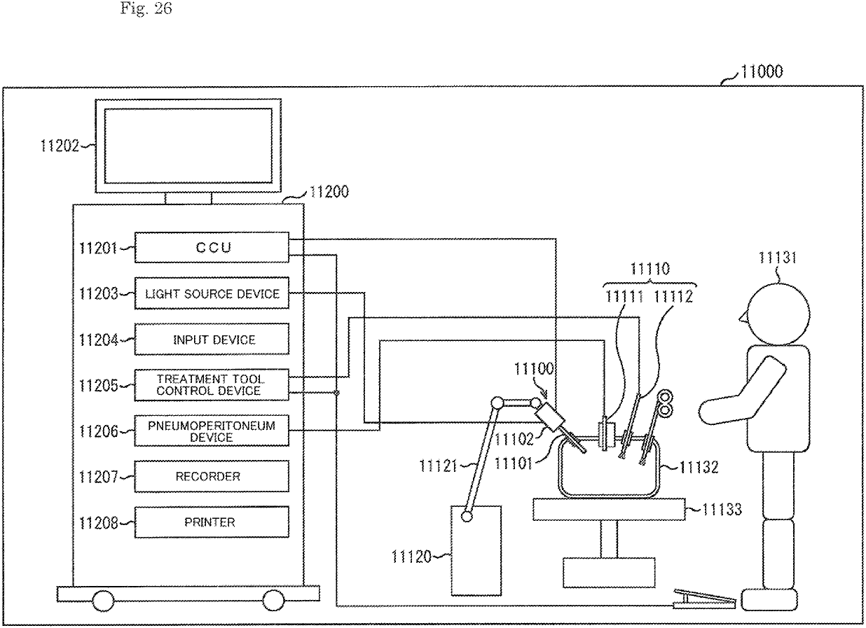

FIG. 26 is a diagram illustrating an example of a schematic configuration of an endoscopic surgery system to which the technology according to the present disclosure (the present technology) can be applied.

FIG. 26 shows a state where a surgeon (doctor) 11131 is performing a surgical operation on a patient 11132 on a patient bed 11133 by using the endoscopic surgery system 11000. As illustrated in the drawing, the endoscopic surgery system 11000 includes an endoscope 11100, other surgical instruments 11110 such as a pneumoperitoneum tube 11111 and an energized treatment tool 11112, a support arm device 11120 that supports the endoscope 11100, and a cart 11200 equipped with various devices for endoscopic operation.

The endoscope 11100 includes a lens barrel 11101, a region of which having a predetermined length from a distal end is inserted into a body cavity of the patient 11132, and a camera head 11102 connected to a proximal end of the lens barrel 11101. Although the endoscope 11100 configured as a so-called rigid mirror having the rigid lens barrel 11101 is illustrated in the illustrated example, the endoscope 11100 may be configured as a so-called flexible mirror having a flexible lens barrel.

An opening in which an objective lens is fitted is provided at the distal end of the lens barrel 11101. A light source device 11203 is connected to the endoscope 11100, and light generated by the light source device 11203 is guided to the distal end of the lens barrel by a light guide extending inside the lens barrel 11101 and is radiated toward the observation target in the body cavity of the patient 11132 via the objective lens. The endoscope 11100 may be a direct-viewing endoscope or may be a perspective endoscope or a side-viewing endoscope.

An optical system and an imaging element are provided inside the camera head 11102, and the reflected light (observation light) from the observation target converges on the imaging element by the optical system. The observation light is photoelectrically converted by the imaging element, and an electrical signal corresponding to the observation light, that is, an image signal corresponding to an observation image is generated. The image signal is transmitted as RAW data to a camera control unit (CCU) 11201.

The CCU 11201 is composed of a central processing unit (CPU), a graphics processing unit (GPU) or the like, and comprehensively controls the operation of the endoscope 11100 and a display device 11202. In addition, the CCU 11201 receives an image signal from the camera head 11102, and performs various types of image processing for displaying an image based on the image signal, for example, development processing (demosaic processing) on the image signal.

The display device 11202 displays an image based on an image signal having been subjected to image processing by the CCU 11201 under the control of the CCU 11201.

The light source device 11203 is constituted by, for example, a light source such as a light emitting diode (LED), and supplies irradiation light at the time of imaging a surgical part or the like to the endoscope 11100.

The input device 11204 is an input interface for the endoscopic surgery system 11000. The user can input various types of information or instructions to the endoscopic surgery system 11000 via the input device 11204. For example, the user inputs an instruction to change imaging conditions (a type of radiated light, a magnification, a focal length, or the like) of the endoscope 11100.

A treatment tool control device 11205 controls the driving of an energized treatment tool 11112 for cauterizing or incising tissue, sealing a blood vessel, or the like. In order to secure a field of view of the endoscope 11100 and secure an operation space of the surgeon, a pneumoperitoneum device 11206 sends gas into the body cavity of the patient 11132 via the pneumoperitoneum tube 11111 in order to inflate the body cavity. A recorder 11207 is a device that can record various types of information related to surgery. A printer 11208 is a device that can print various types of information related to surgery in various formats such as text, images and graphs.

The light source device 11203 that supplies the endoscope 11100 with the radiation light for imaging the surgical part can be configured of, for example, an LED, a laser light source, or a white light source configured of a combination thereof. When a white light source is formed by a combination of RGB laser light sources, it is possible to control an output intensity and an output timing of each color (each wavelength) with high accuracy and thus, the light source device 11203 adjusts white balance of the captured image. Further, in this case, laser light from each of the respective RGB laser light sources is radiated to the observation target in a time division manner, and driving of the imaging element of the camera head 11102 is controlled in synchronization with radiation timing such that images corresponding to respective RGB can be captured in a time division manner. According to this method, it is possible to obtain a color image without providing a color filter to the imaging element.

Further, the driving of the light source device 11203 may be controlled to change the intensity of output light at predetermined time intervals. The driving of the imaging element of the camera head 11102 is controlled in synchronization with the timing of the change in the light intensity to acquire an image in a time-division manner, and the image is synthesized, whereby it is possible to generate a so-called image in a high dynamic range without underexposure or overexposure.

In addition, the light source device 11203 may have a configuration in which light in a predetermined wavelength band corresponding to special light observation can be supplied. In the special light observation, for example, by emitting light in a band narrower than that of irradiation light (that is, white light) during normal observation using wavelength dependence of light absorption in a body tissue, so-called narrow band light observation (narrow band imaging) in which a predetermined tissue such as a blood vessel in the mucous membrane surface layer is imaged with a high contrast is performed. Alternatively, in the special light observation, fluorescence observation in which an image is obtained by fluorescence generated by emitting excitation light may be performed. The fluorescence observation can be performed by emitting excitation light to a body tissue, and observing fluorescence from the body tissue (autofluorescence observation), or locally injecting a reagent such as indocyanine green (ICG) to a body tissue, and emitting excitation light corresponding to a fluorescence wavelength of the reagent to the body tissue to obtain a fluorescence image. The light source device 11203 can supply narrow band light and/or excitation light corresponding to such special light observation.

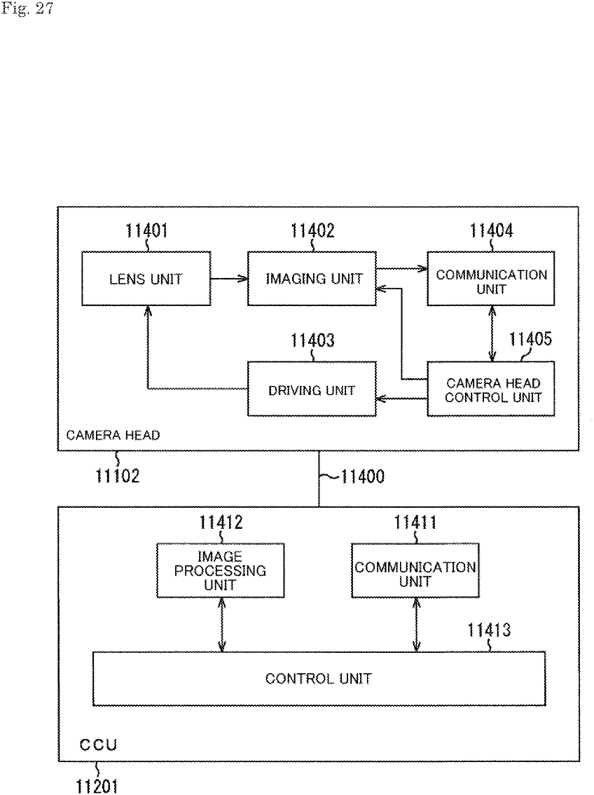

FIG. 27 is a block diagram illustrating an example of a functional configuration of the camera head 11102 and the CCU 11201 illustrated in FIG. 26.

The camera head 11102 includes a lens unit 11401, an imaging unit 11402, a driving unit 11403, a communication unit 11404, and a camera head control unit 11405. The CCU 11201 includes a communication unit 11411, an image processing unit 11412, and a control unit 11413. The camera head 11102 and the CCU 11201 are connected to each other such that they can communicate with each other via a transmission cable 11400.

The lens unit 11401 is an optical system provided at a portion for connection to the lens barrel 11101. Observation light taken from the tip of the lens barrel 11101 is guided to the camera head 11102 and is incident on the lens unit 11401. The lens unit 11401 is constituted by a combination of a plurality of lenses including a zoom lens and a focus lens.

The imaging unit 11402 is constituted by an imaging element. The imaging element constituting the imaging unit 11402 may be one element (so-called single plate type) or a plurality of elements (so-called multi-plate type). When the imaging unit 11402 is configured as a multi-plate type, for example, image signals corresponding to RGB are generated by the imaging elements, and a color image may be obtained by synthesizing the image signals. Alternatively, the imaging unit 11402 may be configured to include a pair of imaging elements for acquiring image signals for the right eye and the left eye corresponding to three-dimensional (3D) display. When 3D display is performed, the surgeon 11131 can ascertain the depth of biological tissues in the surgical part more accurately. Here, when the imaging unit 11402 is configured as a multi-plate type, a plurality of lens units 11401 may be provided according to the imaging elements.

Further, the imaging unit 11402 may not necessarily be provided in the camera head 11102. For example, the imaging unit 11402 may be provided immediately after the objective lens inside the lens barrel 11101.

The driving unit 11403 is constituted by an actuator, and moves the zoom lens and the focus lens of the lens unit 11401 by a predetermined distance along an optical axis under the control of the camera head control unit 11405. Thereby, the magnification and the focus of the image captured by the imaging unit 11402 can be appropriately adjusted.

The communication unit 11404 is configured of a communication device for transmitting or receiving various information to or from the CCU 11201. The communication unit 11404 transmits the image signal obtained from the imaging unit 11402 as RAW data to the CCU 11201 via the transmission cable 11400.

In addition, the communication unit 11404 receives a control signal for controlling driving of the camera head 11102 from the CCU 11201 and supplies the control signal to the camera head control unit 11405. The control signal includes, for example, information on the imaging conditions such as information indicating that the frame rate of the captured image is designated, information indicating that the exposure value at the time of imaging is designated, and/or information indicating that the magnification and the focus of the captured image are designated.

Note that the imaging conditions such as the frame rate, the exposure value, the magnification, and the focus may be appropriately designated by the user, or may be automatically set by the control unit 11413 of the CCU 11201 on the basis of the acquired image signal. In the latter case, a so-called auto exposure (AE) function, auto focus (AF) function and auto white balance (AWB) function are provided in the endoscope 11100.

The camera head control unit 11405 controls the driving of the camera head 11102 on the basis of the control signal from the CCU 11201 received via the communication unit 11404.

The communication unit 11411 is constituted by a communication device for transmitting and receiving various pieces of information to and from the camera head 11102. The communication unit 11411 receives the image signal transmitted from the camera head 11102 via the transmission cable 11400.

In addition, the communication unit 11411 transmits a control signal for controlling the driving of the camera head 11102 to the camera head 11102. The image signal or the control signal can be transmitted through electric communication, optical communication, or the like.

The image processing unit 11412 performs various image processing on the image signal which is the RAW data transmitted from the camera head 11102.

The control unit 11413 performs various kinds of control regarding imaging of an operation site or the like using the endoscope 11100 and a display of a captured image obtained by imaging the operation site or the like. For example, the control unit 11413 generates the control signal for controlling the driving of the camera head 11102.

Further, the control unit 11413 causes the display device 11202 to display the captured image obtained by imaging the operation site or the like on the basis of the image signal having subjected to image processing by the image processing unit 11412. In this case, the control unit 11413 may recognize various objects in the captured image using various image recognition technologies. For example, the control unit 11413 can recognize surgical tools such as forceps, specific biological parts, bleeding, mist when the energized treatment tool 11112 is used and the like by detecting the edge shape and color of the object included in the captured image. When the control unit 11413 causes the display device 11202 to display the captured image, it may cause various types of surgical support information to be superimposed and displayed with the image of the operation site using the recognition result. When the surgical support information is superimposed and displayed, and presented to the surgeon 11131, it is possible to reduce the burden on the surgeon 11131 and the surgeon 11131 can reliably proceed the operation.

The transmission cable 11400 connecting the camera head 11102 and the CCU 11201 to each other is an electric signal cable that supports electric signal communication, an optical fiber that supports optical communication, or a composite cable thereof.

Here, in the example shown in the drawing, communication is performed in a wired manner using the transmission cable 11400, but communication between the camera head 11102 and the CCU 11201 may be performed in a wireless manner.

The example of the endoscopic surgery system to which the technology according to the present disclosure can be applied has been described above. The technology according to the present disclosure may be applied to the imaging unit 11402 of the camera head 11102, and the image processing unit 11412 of the CCU 11201, and the like among the configurations described above. Specifically, the solid-state imaging devices 101 and 1 in FIGS. 1 and 2 can be applied to the imaging unit 10402, and the signal processing circuit 105 in FIG. 1 can be applied to the image processing unit 11412. By applying the technology according to the present disclosure to the imaging unit 10402 and the image processing unit 11412, it is possible to obtain a clearer image of the surgical part and thus, the operator can reliably confirm the surgical part.

Here, although the endoscopic surgery system has been described as an example, the technology according to the present disclosure may be applied to other, for example, a microscopic operation system.

The present technology can also take on the following configurations.

A solid-state imaging device including: a pixel array unit in which a plurality of pixel unit groups is arranged, the pixel unit group being composed of pixel units arranged in a 2×2 matrix, the pixel unit being composed of pixels arranged in a ₘ×ₙ matrix (m and n are natural numbers of 2 or more), the pixel having a photoelectric conversion unit and a color filter formed corresponding to the photoelectric conversion unit, wherein each of the pixel unit groups includes an R-filter as the color filter in one of the four pixel units constituting the pixel unit group, includes a G-filter as the color filter in two of the four pixel units, and includes a B-filter as the color filter in one of the four pixel units, and at least one of the pixel unit group includes a predetermined color filter having a transmittance peak wavelength different from any one of the R-filter, the G-filter, and the B-filter as the color filter.

The solid-state imaging device according to (1), wherein the transmittance peak wavelength of the predetermined color filter is either in a first range larger than a transmittance peak wavelength of the B-filter and less than a transmittance peak wavelength of the G-filter, or in a second range larger than the transmittance peak wavelength of the G-filter and less than a transmittance peak wavelength of the R-filter.

The solid-state imaging device according to (2), wherein the first range is larger than 465 nm and less than 525 nm, and the second range is larger than 535 nm and less than 595 nm.

The solid-state imaging device according to (1) or (2), wherein m and n = 2, and the number of types of the color filters included in one pixel unit is 2 or less.

The solid-state imaging device according to (4), wherein the predetermined color filter is included in the pixel unit including the R-filter or the B-filter among the pixel units constituting the at least one pixel unit group.

The solid-state imaging device according to (4) or (5), wherein the predetermined color filter is included only in a partial pixel unit group among all the pixel unit groups in the pixel array unit.

The solid-state imaging device according to (4) or (5), wherein the predetermined color filter is included in each of all the pixel unit groups of the pixel array unit.

The solid-state imaging device according to (7), wherein each of the pixel units including the predetermined color filter includes the same type of the predetermined color filter in two pixels of one pixel unit.

An electronic device including: a solid-state imaging device including a pixel array unit in which a plurality of pixel unit groups is arranged, the pixel unit group being composed of pixel units arranged in a 2×2 matrix, the pixel unit being composed of pixels arranged in a ₘ×ₙ matrix (m and n are natural numbers of 2 or more), the pixel having a photoelectric conversion unit and a color filter formed corresponding to the photoelectric conversion unit, each of the pixel unit groups including an R-filter as the color filter in one of the four pixel units constituting the pixel unit group, a G-filter as the color filter in two of the four pixel units, and a B-filter as the color filter in one of the four pixel units, and at least one of the pixel unit group including a predetermined color filter having a transmittance peak wavelength different from any one of the R-filter, the G-filter, and the B-filter as the color filter; an optical lens that forms an image light from a subject on an imaging surface of the solid-state imaging device; and a signal processing circuit that performs signal processing on a signal output from the solid-state imaging device.

### REFERENCE SIGNS LIST

1 Solid-state imaging device
2 Substrate
3 Pixel array unit
4 Vertical driving circuit
5 Column signal processing circuit
6 Horizontal driving circuit
7 Output circuit
8 Control circuit
9 Pixel
10 Pixel unit
11 Pixel unit group
12 Pixel drive wiring
13 Vertical signal line
14 Horizontal signal line
15 Insulating film
16 Light shielding film
17 Planarization film
18 Light receiving layer
19 Color filter
20 Microlens
21 Light collecting layer
22 Wiring layer
23 Supporting substrate
24 Photoelectric conversion unit
25 Pixel separation unit
26 Color filter array
27 Microlens array
28 Interlayer insulating film
29 Wiring
30 Mosaic image
31 Image pixel
32 RGB mosaic image
33 Image pixel
34 RGB mosaic image
35 Image pixel
36 RGB mosaic image
37 Image pixel
38 CMY mosaic image
100 Electronic device
101 Solid-state imaging device
102 Optical lens
103 Shutter device
104 Driving circuit
105 Signal processing circuit
106 Incident light

What is claimed is:

1. A solid-state imaging device, comprising:
a pixel array unit in which a plurality of pixel unit groups is arranged, the pixel unit group being composed of pixel units arranged in a 2×2 matrix, the pixel unit being composed of pixels arranged in a mxn matrix (m and n are natural numbers of 2 or more), the pixel having a photoelectric conversion unit and a color filter formed corresponding to the photoelectric conversion unit, wherein
each of the pixel unit groups includes an R-filter as the color filter in one of the four pixel units constituting the pixel unit group, includes a G-filter as the color filter in two of the four pixel units, and includes a B-filter as the color filter in one of the four pixel units, and
at least one of the pixel unit group includes a predetermined color filter having a transmittance peak wavelength different from any one of the R-filter, the G-filter, and the B-filter as the color filter.

2. The solid-state imaging device according to claim 1, wherein
the transmittance peak wavelength of the predetermined color filter is either in a first range larger than a transmittance peak wavelength of the B-filter and less than a transmittance peak wavelength of the G-filter, or in a second range larger than the transmittance peak wavelength of the G-filter and less than a transmittance peak wavelength of the R-filter.

3. The solid-state imaging device according to claim 2, wherein
the first range is larger than 465 nm and less than 525 nm, and the second range is larger than 535 nm and less than 595 nm.

4. The solid-state imaging device according to claim 1, wherein
m and n = 2, and
the number of types of the color filters included in one pixel unit is 2 or less.

5. The solid-state imaging device according to claim 4, wherein
the predetermined color filter is included in the pixel unit including the R-filter or the B-filter among the pixel units constituting the at least one pixel unit group.

6. The solid-state imaging device according to claim 4, wherein
the predetermined color filter is included only in a partial pixel unit group among all the pixel unit groups in the pixel array unit.

7. The solid-state imaging device according to claim 4, wherein
the predetermined color filter is included in each of all the pixel unit groups of the pixel array unit.

8. The solid-state imaging device according to claim 7, wherein
each of the pixel units including the predetermined color filter includes the same type of the predetermined color filter in two pixels of one pixel unit.

9. An electronic device, comprising:
a solid-state imaging device including a pixel array unit in which a plurality of pixel unit groups is arranged, the pixel unit group being composed of pixel units arranged in a 2×2 matrix, the pixel unit being composed of pixels arranged in a m×n matrix (m and n are natural numbers of 2 or more), the pixel having a photoelectric conversion unit and a color filter formed corresponding to the photoelectric conversion unit, each of the pixel unit groups including an R-filter as the color filter in one of the four pixel units constituting the pixel unit group, a G-filter as the color filter in two of the four pixel units, and a B-filter as the color filter in one of the four pixel units, and at least one of the pixel unit group including a predetermined color filter having a transmittance peak wavelength different from any one of the R-filter, the G-filter, and the B-filter as the color filter;
an optical lens that forms an image light from a subject on an imaging surface of the solid-state imaging device; and
a signal processing circuit that performs signal processing on a signal output from the solid-state imaging device.
